(19) United States
(12) Patent Application Publication
(10) Pub. No.: US 2026/0123127 A1
(43) Pub. Date: Apr. 30, 2026

(54) METHOD FOR MANUFACTURING DISPLAY PANEL

(71) Applicant: HKC CORPORATION LIMITED, SHENZHEN (CN)

(72) Inventors: Fengzhen DANG, SHENZHEN (CN); Chuan WU, SHENZHEN (CN); Zhonglin CAO, SHENZHEN (CN); Dongmei WEI, SHENZHEN (CN); Xiaoxiao YUAN, SHENZHEN (CN); Yao LI, SHENZHEN (CN); Jie CHEN, SHENZHEN (CN); Wenyu YI, SHENZHEN (CN); Lidan YE, SHENZHEN (CN)

(73) Assignee: HKC CORPORATION LIMITED, SHENZHEN (CN)

(21) Appl. No.: 19/358,868

(22) Filed: Oct. 15, 2025

(30) Foreign Application Priority Data
Oct. 31, 2024 (CN) 202411547278.0

(51) Int. Cl. H10H 29/01; H10H 29/24

(52) U.S. Cl. CPC H10H 29/012; H10H 29/24

(57) ABSTRACT

The present application provides a method for manufacturing a display panel, including providing a light-emitting carrier board, the light-emitting carrier board including a glass substrate and one or more light-emitting units arranged on a surface of a side of the glass substrate, the light-emitting carrier board being formed by cutting a light-emitting mother board; providing a silicon-based driving substrate; and bonding and connecting the light-emitting carrier board and the silicon-based driving substrate, the one or more light-emitting units being arranged on a side of the glass substrate away from the silicon-based driving substrate, and a size of the silicon-based driving substrate matching a size of the light-emitting carrier board.

### CROSS-REFERENCE TO RELATED APPLICATIONS

The present application claims priority to Chinese Patent Application No. 202411547278.0, entitled “METHOD FOR MANUFACTURING DISPLAY PANEL”, filed on Oct. 31, 2024, which is herein incorporated by reference in its entirety.

### TECHNICAL FIELD

The present disclosure relates to the technical field of displays, in particular, to a method for manufacturing a display panel.

### BACKGROUND

The main feature of a silicon-based micro display lies in that the silicon-based micro display uses monocrystalline silicon as a substrate, and a driving circuit manufactured by a complementary metal-oxide semiconductor (CMOS) process is integrated in a backplane, thereby achieving higher integration and primarily adopting top emission.

A silicon-based organic light emitting diode (OLED) is currently a type of display device that exhibits the best performance in products applied in the fields of augmented reality (AR) or virtual reality (VR). Compared with a conventional active-matrix organic light-emitting diode (AMOLED) device that uses an amorphous silicon, a microcrystalline silicon, or a low-temperature polycrystalline silicon thin film transistor as the backplane, a single-crystal silicon backplane has a higher carrier mobility. By vaporizing a pixel pattern isolation layer on a silicon-based CMOS driving substrate and subsequently vaporizing an anode, an organic layer, and a cathode, a smaller pixel size may be achieved, thus enabling the refinement of a display pixel.

However, during the process of vaporizing a light-emitting unit (i.e., OLED), it is likely to affect the silicon-based driving circuit, resulting in the inoperability of the silicon-based driving circuit and an increase in cost.

### SUMMARY

A first technical solution of the present disclosure is to provide a method for manufacturing a display panel, including: providing a light-emitting carrier board, the light-emitting carrier board including a glass substrate and one or more light-emitting units arranged on a surface of a side of the glass substrate, the light-emitting carrier board being formed by cutting a light-emitting mother board; providing a silicon-based driving substrate; and bonding and connecting the light-emitting carrier board and the silicon-based driving substrate, the one or more light-emitting units being arranged on a side of the glass substrate away from the silicon-based driving substrate, and a size of the silicon-based driving substrate matching a size of the light-emitting carrier board.

A second technical solution of the present disclosure is to provide a method for manufacturing a display panel, including providing a light-emitting carrier board, the light-emitting carrier board including a glass substrate and one or more light-emitting units arranged on a surface of a side of the glass substrate, the light-emitting carrier board being a light-emitting mother board; providing a silicon-based driving substrate; and bonding and connecting the light-emitting carrier board and the silicon-based driving substrate, and cutting the light-emitting carrier board and the silicon-based driving substrate that are bonded and connected, the one or more light-emitting units being arranged on a side of the glass substrate away from the silicon-based driving substrate, and a size of the silicon-based driving substrate matching a size of the light-emitting carrier board.

### BRIEF DESCRIPTION OF THE DRAWINGS

To more clearly illustrate the technical solutions in the embodiments of the present disclosure, a brief introduction to the drawings used in some embodiments of the present disclosure is provided below. It is evident that the drawings described below are only some of the embodiments of the present disclosure. For those skilled in the art, additional drawings may be derived from these drawings without creative work.

FIG. 1 is a flowchart of a method for manufacturing a display panel in some embodiments of the present disclosure.

FIG. 2 is a schematic structural view corresponding to operations S1-10 to S1-30 of FIG. 1 in some embodiments of the present disclosure.

FIG. 3 is a flowchart of operation S1-10 of FIG. 1 in some embodiments of the present disclosure.

FIG. 4 is a flowchart of providing a light-emitting mother board in operations S1-11 of FIG. 3 in some embodiments of the present disclosure.

FIG. 5 is a schematic structural view corresponding to providing a light-emitting mother board in operations S1-11 of FIG. 3 in some embodiments of the present disclosure.

FIG. 6 is a schematic sectional view in an E-E orientation in FIG. 5.

FIG. 7 is a schematic structural view corresponding to operations S1-10 in FIG. 1 in some embodiments of the present disclosure.

FIG. 8 is a schematic sectional view tin a F-F orientation in FIG. 7.

FIG. 9 is a flowchart of a method for manufacturing a display panel in some embodiments of the present disclosure.

FIG. 10 is a flowchart of some embodiments of operation S2-30 in FIG. 9 in some embodiments of the present disclosure.

FIG. 11 is a schematic structural view corresponding to operations S2-10 to S2-30 in FIG. 9 in some embodiments of the present disclosure.

### DETAILED DESCRIPTION

The following provides a detailed description of the embodiments of the present disclosure in conjunction with the drawings of the specification.

In the following description, specific details such as particular system structures, interfaces, and technologies are provided for the purpose of illustration rather than limitation, so as to facilitate a thorough understanding of the present disclosure.

The technical solutions in the embodiments of the present disclosure will be described clearly and completely in the following in conjunction with the accompanying drawings in the embodiments of the present disclosure. It is evident that the embodiments described below are only some of the embodiments of the present disclosure and not all of them. All other embodiments obtained by those skilled in the art without creative effort shall fall within the scope of protection of the present disclosure.

The terms “first,” “second,” and “third” in the present disclosure are merely used for descriptive purposes and should not be construed as indicating or implying relative importance or implicitly indicating the number of the technical features indicated. Thus, features defined with “first,” “second,” and “third” may explicitly or implicitly include at least one such feature. In the description of the present disclosure, the term “multiple” means at least two, for example, two or three, unless specifically defined otherwise. All directional indications (such as up, down, left, right, front, back, etc.) in the embodiments of the present disclosure are only used to describe the relative positional relationship and movement status of components under a specific posture (as shown in the drawings). If the specific posture changes, the directional indications should also be adjusted accordingly. Furthermore, the terms “include,” “have,” and any variations thereof are intended to cover non-exclusive inclusion. For example, a process, a method, a system, a product, or an apparatus that includes a series of steps or components is not limited to those explicitly listed steps or components but may optionally include other steps or components not listed, or may optionally include inherent other steps or components.

References to “embodiment” in the present disclosure mean that a particular feature, structure, or characteristic described in connection with the embodiment is included in at least one embodiment of the present disclosure. The phrase appearing in various places throughout the specification does not necessarily refer to the same embodiment, and embodiments are not mutually exclusive or alternative unless otherwise indicated. It is explicitly and implicitly understood by those skilled in the art that the embodiments described herein may be combined with other embodiments.

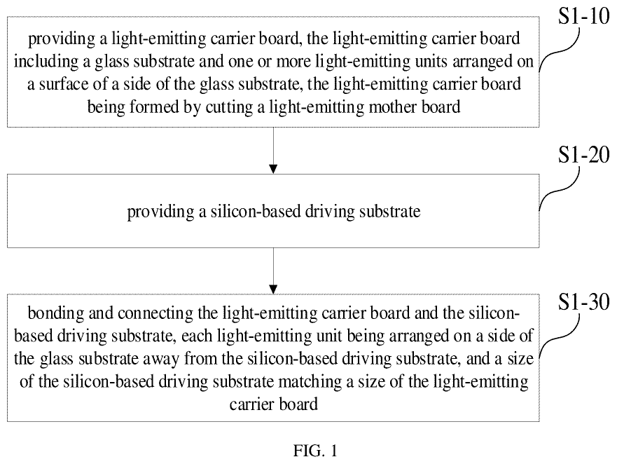

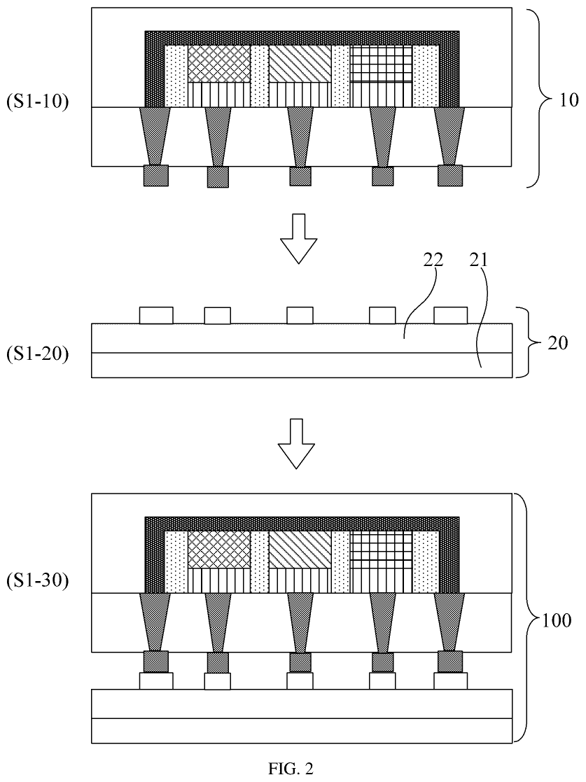

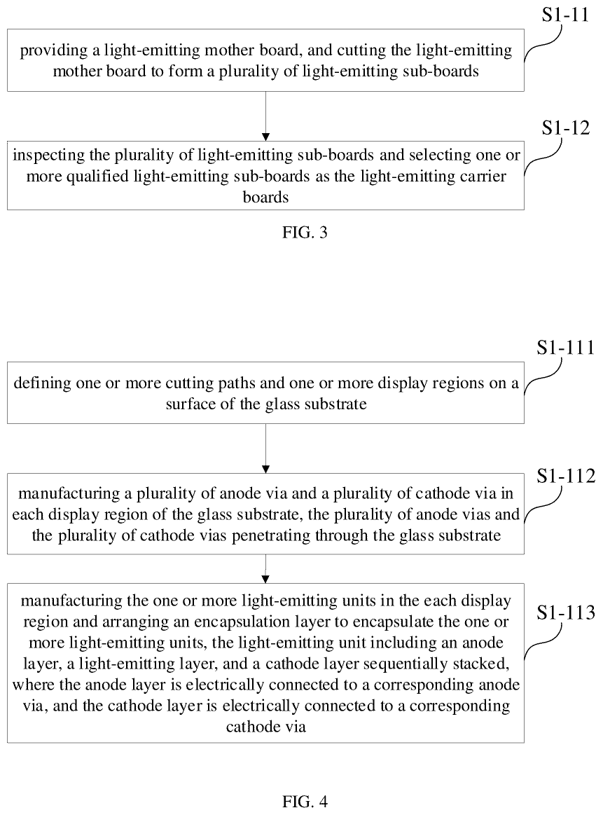

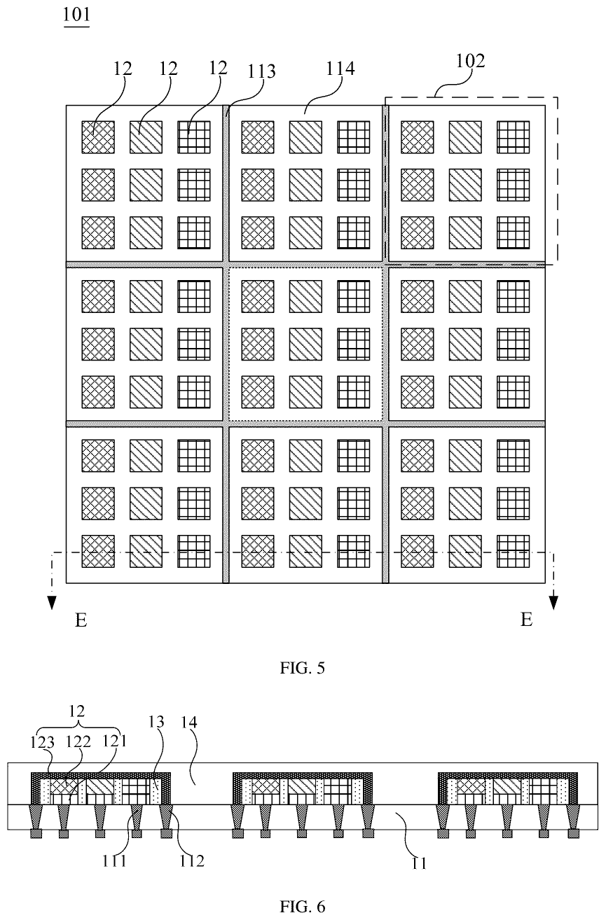

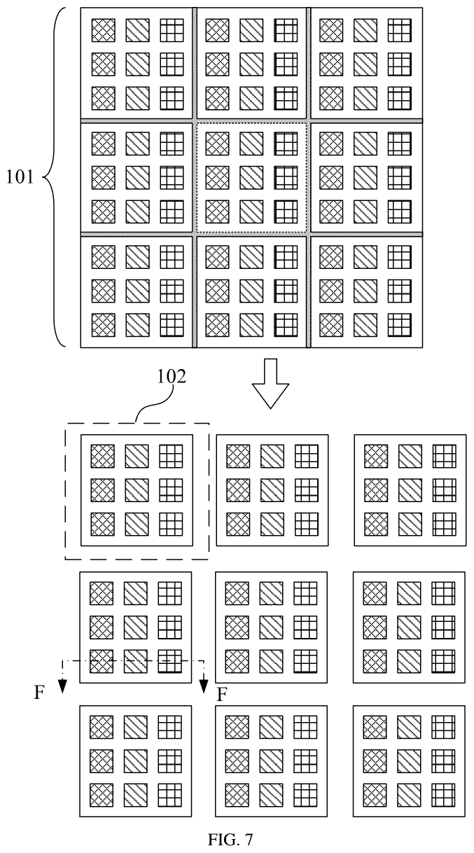

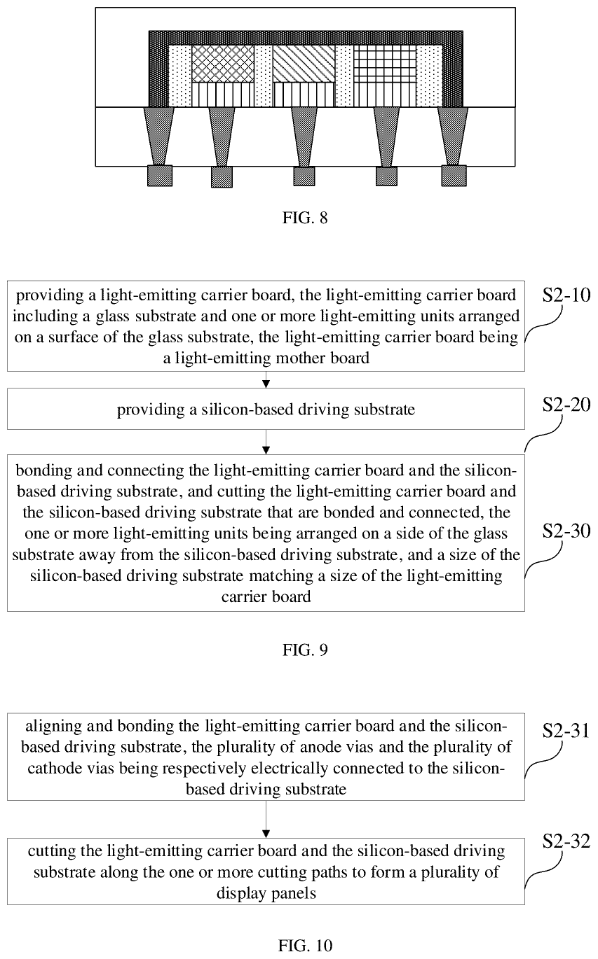

As shown in FIGS. 1 to 8, FIG. 1 is a flowchart of a method for manufacturing a display panel in some embodiments of the present disclosure, FIG. 2 is a schematic structural view corresponding to operations S1-10 to S1-30 of FIG. 1 in some embodiments of the present disclosure, FIG. 3 is a flowchart of operation S1-10 of FIG. 1 in some embodiments of the present disclosure, FIG. 4 is a flowchart of providing a light-emitting mother board in operations S1-11 of FIG. 3 in some embodiments of the present disclosure, FIG. 5 is a schematic structural view corresponding to providing a light-emitting mother board in operations S1-11 of FIG. 3 in some embodiments of the present disclosure, FIG. 6 is a schematic sectional view in an E-E orientation in FIG. 5, FIG. 7 is a schematic structural view corresponding to operations S1-10 in FIG. 1 in some embodiments of the present disclosure, and FIG. 8 is a schematic sectional view tin a F-F orientation in FIG. 7.

The present disclosure provides a method for manufacturing a display panel. The method for manufacturing a display panel includes: providing a light-emitting carrier board 10, the light-emitting carrier board 10 including a glass substrate 11 and one or more light-emitting units 12 arranged on a surface of a side of the glass substrate 1, the light-emitting carrier board 10 being formed by cutting a light-emitting mother board 101; providing a silicon-based driving substrate 20; bonding and connecting the light-emitting carrier board 10 and the silicon-based driving substrate 20, the one or more light-emitting units 12 being arranged on a side of the glass substrate 11 away from the silicon-based driving substrate 20, and a size of the silicon-based driving substrate 20 matching a size of the light-emitting carrier board 10.

In the present disclosure, the silicon-based driving substrate 20 and the light-emitting carrier board 10 are manufactured separately, which may improve production efficiency. In addition, the vaporization process may be prevented from affecting the silicon-based driving substrate 20, thereby reducing the damage to the silicon-based driving substrate 20. Moreover, compared with related arts in which the light-emitting unit 12 is formed on the silicon-based driving substrate 20 and electrically connected to the silicon-based driving substrate 20 through a silicon via, the present disclosure arranges the light-emitting unit 12 on the glass substrate 11 and bonds the light-emitting unit 12 to the silicon-based driving substrate 20 through a glass via, thereby reducing the cost of silicon vias and improving high-frequency electrical characteristics.

In some embodiments, the method for manufacturing a display panel includes the following operations S1-10, S1-20 and S1-30.

Operation S1-10: providing a light-emitting carrier board, the light-emitting carrier board including a glass substrate and one or more light-emitting units arranged on a surface of a side of the glass substrate, the light-emitting carrier board being formed by cutting a light-emitting mother board.

In some embodiments, the light-emitting carrier board 10 is provided. The light-emitting carrier board 10 includes a glass substrate 11 and one or more light-emitting units 12 arranged on a surface of a side of the glass substrate 11. The light-emitting carrier board 10 is formed by cutting the light-emitting mother board 101.

In some embodiment, the providing the light-emitting carrier board in operation S1-10 includes the following operations S1-11 and S1-12.

Operation S1-11: providing a light-emitting mother board, and cutting the light-emitting mother board to form a plurality of light-emitting sub-boards.

In some embodiments, the light-emitting mother board 101 is provided, and the light-emitting mother board 101 is cut to form a plurality of light-emitting sub-boards 102.

In the production and manufacturing of the display panel 100, in order to reduce cost and enable large-scale mass production, the plurality of light-emitting sub-boards 102 are typically formed on a relatively large light-emitting mother board 101. Then, through a cutting process, the relatively large light-emitting mother board 101 is cut into a plurality of individual light-emitting sub-boards 102.

A number of light-emitting units 12 on the light-emitting mother board 101 is not limited herein and may be selected according to actual needs.

For the plurality of light-emitting sub-boards 102 formed by cutting the light-emitting carrier board 10, a size and a shape of each light-emitting sub-board 102 are not limited and may be selected according to actual needs. Each light-emitting sub-board 102 may have a same or a different shape. Each light-emitting sub-boards 102 may have a same or a different size.

In some embodiments of the present disclosure, the size and the shape of all the light-emitting sub-boards 102 are the same. The shape of each light-emitting sub-board 102 is square.

In some embodiments, a cross-sectional shape of the light-emitting sub-board 102 may be circular, triangular, pentagonal, or other regular or irregular shapes.

In some embodiments, the providing the light-emitting mother board in operation S1-11 includes the following operations S1-111, S1-112 and S1-113.

Operation S1-111: defining one or more cutting paths and one or more display regions on a surface of the glass substrate.

In some embodiments, one or more cutting paths 113 and one or more display regions 114 are defined on a surface of the glass substrate 11. Each display region 114 is configured for the one or more light-emitting units 12, and each cutting path 113 is configured for cutting, so as to reduce damage to the one or more light-emitting units 12 in each display region 114 during the subsequent cutting process of the light-emitting mother board 101 along the one or more cutting paths 113.

Operation S1-112: manufacturing a plurality of anode via and a plurality of cathode via in each display region of the glass substrate, the plurality of anode vias and the plurality of cathode vias penetrating through the glass substrate.

In some embodiments, a plurality of anode vias 111 and a plurality of cathode vias 112 are manufactured in each display region 114 of the glass substrate 11. In a thickness direction of the glass substrate 11, the plurality of anode vias 111 and the plurality of cathode vias 112 penetrate through the glass substrate 11.

Operation S1-113: manufacturing the one or more light-emitting units in the each display region and arranging an encapsulation layer to encapsulate the one or more light-emitting units, the light-emitting unit including an anode layer, a light-emitting layer, and a cathode layer sequentially stacked, where the anode layer is electrically connected to a corresponding anode via, and the cathode layer is electrically connected to a corresponding cathode via.

In some embodiments, the one or more light-emitting units 12 are manufactured in each display region 114, and the one or more light-emitting units 12 are encapsulated by an encapsulation layer 14. Each light-emitting unit 12 includes an anode layer 121, a light-emitting layer 122, and a cathode layer 123 sequentially stacked. The anode layer 121 is electrically connected to a corresponding anode via 111, and the cathode layer 123 is electrically connected to a corresponding cathode via 112.

The one or more light-emitting units 12 are OLEDs. At least one color of the one or more light-emitting units 12 are arranged on the light-emitting mother board 101. Each light-emitting unit 12 emits a light of a single color. The color or a number of colors of the one or more light-emitting units 12 is not limited herein, and the selection may be made according to actual needs.

In some embodiments, the anode layer 121 is arranged on a surface of a side of the glass substrate 11. Each light-emitting carrier board 10 includes light-emitting units 12 of three different colors. The light emitted by the three different colors of light-emitting units 12 is red, green, and blue, respectively. In each light-emitting carrier board 10, the light-emitting units 12 are arranged in a matrix.

In some embodiments, in the light-emitting carrier board 10, a plurality of light-emitting units 12 may be arranged in other configurations, which are not limited herein and may be selected according to actual needs.

In some embodiments, each light-emitting unit 12 corresponds to an anode via 111, and the each light-emitting unit 12 covers a corresponding anode via 111.

In some embodiments, each light-emitting unit 12 may correspond to a plurality of anode vias 111; and/or in a direction parallel to the glass substrate 11, the light-emitting unit 12 and the corresponding anode via 111 may be arranged in an offset or a tangent configuration.

In some embodiments, each cathode via 112 is located at an edge of each light-emitting carrier board 10.

In some embodiments, in a direction parallel to the glass substrate 11, the cathode via 112 is provided between at least part of the light-emitting units 12.

In some embodiments, both the cathode via 112 and the anode via 111 are filled with a conductive material. The material of the conductive material is not limited herein and may be selected according to actual needs.

In some embodiments, the size of the light-emitting unit 12 is 6 micrometers to 15 micrometers.

In some embodiments, the size of the light-emitting unit 12 may be other values.

The light-emitting unit 12 may be manufactured using a fine metal mask (FMM) process, or may be manufactured using a non-FMM process, which is not limited herein and may be selected according to actual needs.

An isolation structure 13 is also required to be provided between the light-emitting units 12, so as to isolate the light-emitting layers 122 of light-emitting units 12 of different colors and avoid pixel crosstalk.

In some embodiments of the present disclosure, the light-emitting unit 12 is manufactured using the FMM process. The isolation structure 13 is made of a non-conductive insulating material. The cathode layer 123 is located on a side of the isolation structure 13 away from the glass substrate 11. The isolation structure 13 only serves to isolate the light-emitting layers 122 of the light-emitting units 12.

In some embodiments, the light-emitting unit 12 may be manufactured using a non-FMM process. The isolation structure 13 includes a conductive portion. The conductive portion is configured to electrically connect the cathode layers 123 of adjacent light-emitting units 12. The isolation structure 13 not only serves to physically separate the light-emitting layers 122 of the light-emitting units 12, but also serves to physically separate the cathode layers 123 of the light-emitting units 12.

The encapsulation layer 14 covers the one or more light-emitting units 12 and the isolation structure 13. The material of the encapsulation layer 14 is not limited herein and may be selected according to actual needs.

The encapsulation layer 14 at least covers the one or more display regions 114. The encapsulation layer 14 may or may not cover the one or more cutting paths 113.

In some embodiments of the present disclosure, the encapsulation layer 14 covers the one or more display regions 114 and the one or more cutting path 113.

In some embodiments, the manufacturing the plurality of anode vias 111 and the plurality of cathode vias 112 in the each display region 114 of the glass substrate 11 is performed after the manufacturing the one or more light-emitting units 12 in the each display region 114 and arranging the encapsulation layer 14 to encapsulate the one or more light-emitting units 12.

In some embodiments, the manufacturing the plurality of anode vias 111 and the plurality of cathode vias 112 in the each display region 114 of the glass substrate 11 is performed before the manufacturing the one or more light-emitting units 12 in the each display region 114 and arranging the encapsulation layer 14 to encapsulate the one or more light-emitting units. That is, the operation S1-112 is performed before the operation S1-113

Operation S1-12: inspecting the plurality of light-emitting sub-boards and selecting one or more qualified light-emitting sub-boards as the light-emitting carrier boards.

In some embodiments, the plurality of light-emitting sub-boards 102 are inspected, and those that are qualified are selected as the light-emitting carrier boards 10.

It should be understood that during the process of cutting the light-emitting mother board 101 to form the plurality of light-emitting sub-boards 102, there may be a certain yield loss to the glass substrate 11 of the plurality of light-emitting sub-boards 102. Therefore, the plurality of light-emitting sub-boards 102 are inspected first to identify defective ones in advance and prevent them from entering the subsequent bonding process, which may otherwise cause waste of the silicon-based driving substrates 20 and reduce the yield.

It should be noted that all light-emitting sub-boards 102 may be referred to as light-emitting carrier boards 10. For the purpose of improving the bonding yield in the subsequent operations, only the light-emitting sub-boards 102 that pass the inspection are selected as the light-emitting carrier boards 10 in some embodiments of the present disclosure.

Operation S1-20: providing a silicon-based driving substrate.

In some embodiments, the silicon-based driving substrate 20 is provided.

The silicon-based driving substrate 20 includes a silicon substrate 21 and a driving circuit layer 22.

The silicon substrate 21 refers to a substrate made of single-crystal silicon material.

The driving circuit layer 22 includes an active driving circuit integrated on the silicon substrate 21 using the CMOS process (not shown in the drawings).

It should be noted that there is no fixed order between the operation S1-10 and the operation S1-20. The operation S1-10 and the operation S1-20 may be performed simultaneously, or the operation S1-10 may be performed before or after the operation S1-20.

Operation S1-30: bonding and connecting the light-emitting carrier board and the silicon-based driving substrate, each light-emitting unit being arranged on a side of the glass substrate away from the silicon-based driving substrate, and a size of the silicon-based driving substrate matching a size of the light-emitting carrier board.

In some embodiments, the light-emitting carrier board 10 is bonded and connected to the silicon-based driving substrate 20. The one or more light-emitting units 12 are arranged on the side of the glass substrate 11 away from the silicon-based driving substrate 20, and the size of the silicon-based driving substrate 20 matches that of the light-emitting carrier board 10.

In some embodiments of the present disclosure, the silicon-based driving substrate 20 and the light-emitting carrier board 10 are manufactured separately, which may improve production efficiency. In addition, the vaporization process is prevented from affecting the silicon-based driving substrate 20, thereby reducing damage to the silicon-based driving substrate 20. That is to say, from a process perspective, separately manufacturing the silicon-based driving substrate 20 and the light-emitting carrier board 10 not only improves the yield but also reduces the cost.

In some embodiments, the bonding and connecting the light-emitting carrier board and the silicon-based driving substrate in the operation S1-30 includes: aligning and bonding the light-emitting carrier board with the silicon-based driving substrate to form a display panel, the plurality of anode vias and the plurality of cathode vias being respectively electrically connected to the silicon-based driving substrate.

It should be understood that, compared with silicon via technology, glass via technology has the advantages of excellent high-frequency electrical characteristics, low cost, simple process flow, and strong mechanical stability.

Compared with related arts in which the light-emitting unit 12 is formed on the silicon-based driving substrate 20 and electrically connected to the silicon-based driving substrate 20 through a silicon via, the present disclosure arranges the light-emitting unit 12 on the glass substrate 11 and bonds the light-emitting unit 12 to the silicon-based driving substrate 20 through a glass via, thereby reducing the cost of silicon vias and improving high-frequency electrical characteristics.

It may be understood that, compared with existing micro organic light-emitting diodes (Micro OLED) technologies, the present disclosure, by separately manufacturing the silicon-based driving substrate 20 and the light-emitting carrier board 10 may improve production efficiency and reduce cost. The present disclosure, by arranging the light-emitting unit 12 on the glass substrate 11 and bonding it to the silicon-based driving substrate 20 via the glass via may further reduce the cost of silicon vias and improve high-frequency electrical characteristics. In addition, the present disclosure first manufactures the light-emitting mother board 101 and cuts it into a plurality of light-emitting carrier boards 10, which are then bonded with the silicon-based driving substrate 20. This may also simplify the manufacturing process and reduce the cost of the display panel 100.

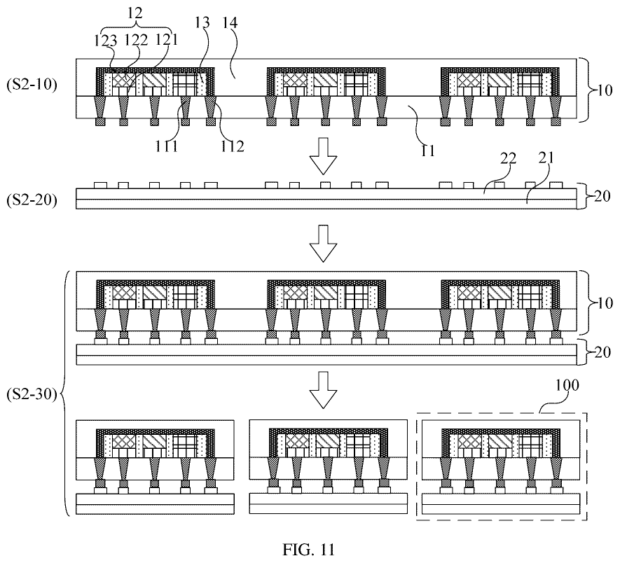

As shown in FIGS. 1 to 11, FIG. 9 is a flowchart of a method for manufacturing a display panel in some embodiments of the present disclosure, FIG. 10 is a flowchart of some embodiments of operation S2-30 in FIG. 9 in some embodiments of the present disclosure, and FIG. 11 is a schematic structural view corresponding to operations S2-10 to S2-30 in FIG. 9 in some embodiments of the present disclosure.

The present disclosure provides a method for manufacturing a display panel. The method for manufacturing a display panel includes: providing a light-emitting carrier board 10, the light-emitting carrier board 10 including a glass substrate 11 and one or more light-emitting units 12 arranged on a surface of a side of the glass substrate 11, the light-emitting carrier board 10 being a light-emitting mother board 101; providing a silicon-based driving substrate 20; bonding and connecting the light-emitting carrier board 10 and the silicon-based driving substrate 20, and cutting the light-emitting carrier board and the silicon-based driving substrate that are bonded and connected, the one or more light-emitting units 12 being arranged on a side of the glass substrate 11 away from the silicon-based driving substrate 20, and a size of the silicon-based driving substrate 20 matching a size of the light-emitting carrier board 10.

In the present disclosure, the silicon-based driving substrate 20 and the light-emitting carrier board 10 are manufactured separately, which may improve production efficiency. In addition, the vaporization process may be prevented from affecting the silicon-based driving substrate 20, thereby reducing the damage to the silicon-based driving substrate 20. Moreover, compared with related arts in which the light-emitting unit 12 is formed on the silicon-based driving substrate 20 and electrically connected to the silicon-based driving substrate 20 through a silicon via, the present disclosure arranges the light-emitting unit 12 on the glass substrate 11 and bonds the light-emitting unit 12 to the silicon-based driving substrate 20 through a glass via, thereby reducing the cost of silicon vias and improving high-frequency electrical characteristics.

In some embodiments, the method for manufacturing a display panel includes the following operations S2-10, S2-20 and S2-30.

Operation S2-10: providing a light-emitting carrier board, the light-emitting carrier board including a glass substrate and one or more light-emitting units arranged on a surface of the glass substrate, the light-emitting carrier board being a light-emitting mother board.

In some embodiments, a light-emitting carrier board 10 is provided. The light-emitting carrier board 10 includes a glass substrate 11 and the one or more light-emitting units 12 arranged on a surface of the glass substrate 11. The light-emitting carrier board 10 is a light-emitting mother board 101.

The structure of the light-emitting mother board 101 is described above and shown in FIGS. 5 and 6, and will not be repeated here.

In some embodiments, the providing the light-emitting carrier board in the operation S2-10 includes the following operations S2-11, S2-12 and S2-13.

Operation S2-11: defining one or more cutting paths and one or more display regions on a surface of the glass substrate.

Operation S2-12: manufacturing a plurality of anode vias and a plurality of cathode vias in each display region of the glass substrate, the plurality of anode vias and the plurality of cathode vias penetrating through the glass substrate.

Operation S2-13: manufacturing the one or more light-emitting units in the each display region, and arranging an encapsulation layer to encapsulate the one or more light-emitting units, each light-emitting unit including an anode layer, a light-emitting layer, and a cathode layer sequentially stacked.

The operation S2-11 is the same as the operation S1-111, which may be referred to above, and will not be repeated here.

The operation S2-12 is the same as the operation S1-112, which may be referred to above, and will not be repeated here.

The operation S2-13 is the same as the operation S1-113, which may be referred to above, and will not be repeated here.

Operation S2-20: providing a silicon-based driving substrate.

In some embodiments, the silicon-based driving substrate 20 is provided.

The structure and manufacturing sequence of the silicon-based driving substrate 20 are described above and will not be repeated here.

Operation S2-30: bonding and connecting the light-emitting carrier board and the silicon-based driving substrate, and cutting the light-emitting carrier board and the silicon-based driving substrate that are bonded and connected, the one or more light-emitting units being arranged on a side of the glass substrate away from the silicon-based driving substrate, and a size of the silicon-based driving substrate matching a size of the light-emitting carrier board.

In some embodiments, the light-emitting carrier board 10 is bonded and connected to the silicon-based driving substrate 20, and the light-emitting carrier board 10 and the silicon-based driving substrate 20 that are bonded and connected are cut. The one or more light-emitting units 12 are arranged on the side of the glass substrate 11 away from the silicon-based driving substrate 20, and the size of the silicon-based driving substrate 20 matches the size of the light-emitting carrier board 10.

In some embodiments, the bonding and connecting the light-emitting carrier board and the silicon-based driving substrate and cutting the light-emitting carrier board and the silicon-based driving substrate that are bonded and connected in the operation S2-30 includes the following operations S2-31 and S2-32.

Operation S2-31: aligning and bonding the light-emitting carrier board and the silicon-based driving substrate, the plurality of anode vias and the plurality of cathode vias being respectively electrically connected to the silicon-based driving substrate.

In some embodiments, the light-emitting carrier board 10 is aligned and bonded with the silicon-based driving substrate 20. The plurality of anode vias 111 and the plurality of cathode vias 112 are respectively electrically connected to the silicon-based driving substrate 20.

The size of the light-emitting carrier board 10 matches the size of the silicon-based driving substrate 20.

Operation S2-32: cutting the light-emitting carrier board and the silicon-based driving substrate along the one or more cutting paths to form a plurality of display panels.

In some embodiments, the light-emitting carrier board 10 and the silicon-based driving substrate 20 that are bonded are cut along the one or more cutting paths 113 to form the plurality of display panels 100.

In some embodiments, after the bonding and connecting the light-emitting carrier board and the silicon-based driving substrate and cutting the light-emitting carrier board and the silicon-based driving substrate that are bonded and connected in the operation S1-30, the method further includes: inspecting the plurality of display panels.

In some embodiments, the plurality of display panels 100 are inspected.

It should be understood that during the cutting process in which the light-emitting mother board 101 and the silicon-based driving substrate 20 are bonded first and then cut into the plurality of display panels 100, there may be a certain degree of yield loss to the glass substrate 11 and the silicon-based driving substrate 20. By inspecting the display panels 100 after cutting, defective products may be removed.

In the above embodiments, the descriptions of the various embodiments emphasize different aspects. The parts not described in detail in a particular embodiment may refer to the relevant descriptions in other embodiments.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A method for manufacturing a display panel, comprising:
providing a light-emitting carrier board, the light-emitting carrier board comprising a glass substrate and one or more light-emitting units arranged on a surface of a side of the glass substrate, the light-emitting carrier board being formed by cutting a light-emitting mother board;
providing a silicon-based driving substrate; and
bonding and connecting the light-emitting carrier board and the silicon-based driving substrate, the one or more light-emitting units being arranged on a side of the glass substrate away from the silicon-based driving substrate, and a size of the silicon-based driving substrate matching a size of the light-emitting carrier board.

2. The method for manufacturing a display panel according to claim 1, wherein the providing the light-emitting carrier board comprises:
providing the light-emitting mother board and cutting the light-emitting mother board to form a plurality of light-emitting sub-boards; and
inspecting the plurality of light-emitting sub-boards and selecting one or more qualified light-emitting sub-boards as the light-emitting carrier boards.

3. The method for manufacturing a display panel according to claim 2, wherein the providing the light-emitting mother board comprises:
defining one or more cutting paths and one or more display regions on a surface of the glass substrate;
manufacturing a plurality of anode vias and a plurality of cathode vias in each display region of the glass substrate, the plurality of anode vias and the plurality of cathode vias penetrating through the glass substrate; and
manufacturing the one or more light-emitting units in the each display region, and arranging an encapsulation layer to encapsulate the one or more light-emitting units, each light-emitting unit comprising an anode layer, a light-emitting layer, and a cathode layer sequentially stacked;
wherein the anode layer is electrically connected to a corresponding anode via, and the cathode layer is electrically connected to a corresponding cathode via.

4. The method for manufacturing a display panel according to claim 3, wherein the manufacturing the plurality of anode vias and the plurality of cathode vias in the each display region of the glass substrate is performed after the manufacturing the one or more light-emitting units in the each display region and arranging the encapsulation layer to encapsulate the one or more light-emitting units.

5. The method for manufacturing a display panel according to claim 3, wherein the manufacturing the plurality of anode vias and the plurality of cathode vias in the each display region of the glass substrate is performed before the manufacturing the one or more light-emitting units in the each display region and arranging the encapsulation layer to encapsulate the one or more light-emitting units.

6. The method for manufacturing a display panel according to claim 3, wherein the bonding and connecting the light-emitting carrier board and the silicon-based driving substrate comprises:
aligning and bonding the light-emitting carrier board and the silicon-based driving substrate to form a display panel, the plurality of anode vias and the plurality of cathode vias being respectively electrically connected to the silicon-based driving substrate.

7. The method for manufacturing a display panel according to claim 3, wherein the one or more light-emitting units arranged on the light-emitting mother board comprise at least one color.

8. The method for manufacturing a display panel according to claim 3, wherein the anode layer is arranged on a surface of a side of the glass substrate, the one or more light-emitting units arranged on the light-emitting carrier board comprising three different colors, and the one or more light-emitting units arranged on the light-emitting carrier board are arranged in a matrix.

9. The method for manufacturing a display panel according to claim 3, wherein the each light-emitting unit corresponds to a corresponding anode via, and the each light-emitting units covers the corresponding anode via.

10. The method for manufacturing a display panel according to claim 3, wherein the each light-emitting unit corresponds to a corresponding plurality of anode vias, and the each light-emitting unit and the corresponding plurality of anode vias are arranged in an offset or tangent configuration in a direction parallel to the glass substrate.

11. The method for manufacturing a display panel according to claim 3, wherein in a case where there are a plurality of light-emitting units, the plurality of cathode vias are located at an edge of the light-emitting carrier board, and one or more cathode vias of the plurality of cathode vias are arranged between at least part of adjacent two of the plurality of light-emitting units.

12. The method for manufacturing a display panel according to claim 3, wherein a size of the each light-emitting unit ranges from 6 micrometers to 15 micrometers.

13. The method for manufacturing a display panel according to claim 11, wherein an isolation structure is arranged between adjacent two of the plurality of light-emitting units, and the isolation structure isolates corresponding light-emitting layers of the plurality of light-emitting units having different colors.

14. The method for manufacturing a display panel according to claim 13, wherein in a case where the plurality of light-emitting unit are manufactured using a fine metal mask (FMM) process, the isolation structure is made of a non-conductive insulating material, the cathode layer is located on a side of the isolation structure away from the glass substrate, the isolation structure isolates corresponding light-emitting layers of the adjacent two of the plurality of light-emitting units;
in a case where the plurality of light-emitting units are manufactured using a non-FMM process, the isolation structure comprises a conductive portion, the conductive portion is configured to electrically connect corresponding cathode layers of adjacent light-emitting units, the isolation structure physically isolates the corresponding light-emitting layers of the adjacent two of the plurality of light-emitting units and physically separates corresponding cathode layers of the adjacent two of the plurality of light-emitting units.

15. The method for manufacturing a display panel according to claim 13, wherein the encapsulation layer covers the plurality of light-emitting units, each isolation structure arranged between the adjacent two of the plurality of light-emitting units, the one or more display regions, and the one or more cutting paths.

16. The method for manufacturing a display panel according to claim 13, wherein the encapsulation layer covers the plurality of light-emitting units, each isolation structure arranged between the adjacent two of the plurality of light-emitting units, and the one or more display regions.

17. A method for manufacturing a display panel, comprising:
providing a light-emitting carrier board, the light-emitting carrier board comprising a glass substrate and one or more light-emitting units arranged on a surface of a side of the glass substrate, the light-emitting carrier board being a light-emitting mother board;
providing a silicon-based driving substrate; and
bonding and connecting the light-emitting carrier board and the silicon-based driving substrate, and cutting the light-emitting carrier board and the silicon-based driving substrate that are bonded and connected, the one or more light-emitting units being arranged on a side of the glass substrate away from the silicon-based driving substrate, and a size of the silicon-based driving substrate matching a size of the light-emitting carrier board.

18. The method for manufacturing a display panel according to claim 17, wherein the providing the light-emitting carrier board comprises:
defining one or more cutting paths and one or more display regions on a surface of the glass substrate;
manufacturing a plurality of anode vias and a plurality of cathode vias in each display region of the glass substrate, the plurality of anode vias and the plurality of cathode vias penetrating through the glass substrate; and
manufacturing the one or more light-emitting units in the each display region, and arranging an encapsulation layer to encapsulate the one or more light-emitting units, each light-emitting unit comprising an anode layer, a light-emitting layer, and a cathode layer sequentially stacked;
wherein the anode layer is electrically connected to a corresponding anode via, and the cathode layer is electrically connected to a corresponding cathode via.

19. The method for manufacturing a display panel according to claim 18, wherein the bonding and connecting the light-emitting carrier board and the silicon-based driving substrate and cutting the light-emitting carrier board and the silicon-based driving substrate that are bonded and connected comprises:
aligning and bonding the light-emitting carrier board and the silicon-based driving substrate, the plurality of anode vias and the plurality of cathode vias being respectively electrically connected to the silicon-based driving substrate; and
cutting the light-emitting carrier board and the silicon-based driving substrate along the one or more cutting paths to form a plurality of display panels.

20. The method for manufacturing a display panel according to claim 17, wherein after bonding and connecting the light-emitting carrier board and the silicon-based driving substrate and cutting the light-emitting carrier board and the silicon-based driving substrate that are bonded and connected, the method further comprises:
inspecting the display panel.
